(19) United States
(12) Patent Application Publication
(10) Pub. No.: US 2009/0285245 A1
(43) Pub. Date: Nov. 19, 2009

(54) FIBER-BASED ULTRAFAST LASER

(76) Inventors: Jian Liu, Sunnyvale, CA (US); Lihmei Yang, Palo Alto, CA (US)

Correspondence Address: JOHN MARTIN TABOADA, 1923 N. NEW BRAUNFELS, SAN ANTONIO, TX, 78208, US

(21) Appl. No.: 12/110,330

(22) Filed: Apr. 27, 2008

Related U.S. Application Data
(60) Provisional application No. 60/937,332, filed on Jun. 27, 2007.
(60) Provisional application No. 60/927,605, filed on May 4, 2007.

(51) Int. Cl. H01S 3/30; H01S 3/10; H01S 5/00

(52) U.S. Cl. 372/6; 372/25; 372/27; 372/50.22; 372/50.11

(57) ABSTRACT

An ultrafast laser system includes a seed laser that provides a signal laser pulse and a fiber-based first chirped reflective Bragg grating that reflects the signal laser pulse propagating along a first path and produce a stretched laser pulse longer than the signal laser pulse. A grating frequency of the first chirped reflective Bragg grating varies along the first path. An amplifier can amplify the stretched laser pulse and output an amplified laser pulse. A second chirped reflective Bragg grating can reflect the amplified laser pulse and produce a compressed laser pulse shorter than the amplified laser pulse. The amplified laser pulse propagates along a second path in the second chirped reflective Bragg grating. A grating frequency of the second chirped reflective Bragg grating varies in an opposite direction along the second path as the grating frequency of the first chirped reflective Bragg grating varies along the first path.

The present patent application claims priority to the U.S. provisional patent application 60/937,332, titled “A compact high energy ultrafast fiber laser”, filed Jun. 27, 2007, and provisional patent application 60/927,605, titled “An all fiber based ultrafast fiber laser”, filed May 4, 2007, the content of which is incorporated herein by reference.

### BACKGROUND

The present invention relates to ultrafast laser systems.

Chirped pulse amplification (CPA) is a common technique for producing short laser pulses. An input laser pulse is first stretched, then amplified, and then compressed to produce an amplified short laser pulse as output. For example, an ultrafast laser pulse typically has pulse width shorter than 1 nanosecond. An input ultrafast pulse is stretched prior to amplification. After amplification, the stretched, amplified, high energy laser pulse is compressed to produce an output ultrafast laser pulse. PA laser systems are commonly implemented using high precision gratings. A grating pair can be used for stretching ultrafast input laser pulses before amplification. Another grating pair is used for compressing the amplified high-energy laser pulse. The gratings are typically required to be matched and precisely aligned, which increases the cost and complexity in the CP laser system.

There is therefore a need for a high-energy ultrafast laser system that is simple and compact, easier to implement, and less costly.

### SUMMARY

In a general aspect, the present invention relates to an ultrafast laser system that includes a seed laser that can provide a signal laser pulse and a first chirped reflective Bragg grating constructed in an optical fiber. The first chirped reflective Bragg grating can reflect the signal laser pulse and produce a stretched laser pulse longer than the signal laser pulse, wherein the signal laser pulse propagates along a first path in the first chirped reflective Bragg grating. A grating frequency of the first chirped reflective Bragg grating varies along the first path. An amplifier can amplify the stretched laser pulse and output an amplified laser pulse; a second chirped reflective Bragg grating that can reflect the amplified laser pulse and produce a compressed laser pulse shorter than the amplified laser pulse. The amplified laser pulse propagates along a second path in the second chirped reflective Bragg grating. A grating frequency of the second chirped reflective Bragg grating varies in an opposite direction along the second path as the grating frequency of the first chirped reflective Bragg grating varies along the first path. An output coupler can output at least a portion of the compressed laser pulse. The compressed laser pulse has a compressed pulse width shorter than 1 nanosecond.

In another general aspect, the present invention relates to an ultrafast laser system that includes a seed laser that can provide a signal laser pulse; a chirped reflective Bragg grating that can reflect the signal laser pulse and produce a stretched laser pulse longer than the signal laser pulse, wherein the signal laser pulse propagates along a first direction in the chirped reflective Bragg grating, wherein a grating frequency of the chirped reflective Bragg grating varies along the first direction; an amplifier that can amplify the stretched laser pulse and output an amplified laser pulse, wherein the amplified laser pulse can propagate along a second direction in the chirped reflective Bragg grating, wherein the second direction is opposite to the first direction, wherein the chirped reflective Bragg grating can reflect the amplified laser pulse and produce a compressed laser pulse shorter than the amplified laser pulse; and an output coupler that can output at least a portion of the compressed laser pulse, wherein the compressed laser pulse has a compressed pulse width shorter than 1 nanosecond.

In another general aspect, the present invention relates to a seed laser system that includes a laser pump source that can provide a pump laser beam, a gain fiber that can produce a signal laser pulse in response to the pump laser beam, a combiner that can couple the pump laser beam into the gain fiber, chirped reflective Bragg grating that can reflect the signal laser pulse and produce a stretched signal laser pulse longer than the signal laser pulse, wherein the stretched signal laser pulse is longer than the signal laser pulse, one or more optical fibers that can allow propagation of the signal laser pulse between the gain fiber and the chirped reflective Bragg grating, and an output coupler that can output at least a portion of the stretched signal laser pulse.

Implementations of the system may include one or more of the following. The grating frequency of the first chirped reflective Bragg grating can increase along the first path, wherein the grating frequency of the second chirped reflective Bragg grating decreases along the second path. The grating frequency of the first chirped reflective Bragg grating can decrease along the first path, wherein the grating frequency of the second chirped reflective Bragg grating increases along the second path. The first chirped reflective Bragg grating can produce a positive optical dispersion in the signal laser pulse, wherein the second chirped reflective Bragg grating produces a negative optical dispersion in the amplified laser pulse. The first chirped reflective Bragg grating can produce a negative optical dispersion in the signal laser pulse, wherein the second chirped reflective Bragg grating produces a positive optical dispersion in the amplified laser pulse. The ultrafast laser system can further include one or more optical fibers configured to allow propagation of the signal laser pulse, the stretched laser pulse, the amplified laser pulse, and the compressed laser pulse between the seed laser and the second chirped reflective Bragg grating. The one or more optical fibers can include at least one polarization maintaining fiber. The second chirped reflective Bragg grating can be constructed by a single-piece bulk component. The second chirped reflective Bragg gratin, can be constructed in an optical fiber. The first chirped reflective Bragg grating and the second chirped reflective Bragg grating can be implemented by a shared chirped reflective Bragg grating, wherein the first path is opposite to the second path in the shared chirped reflective Bragg grating. The compressed pulse width can be shorter than 100 picoseconds. The compressed pulse width can be shorter than 1 picosecond. The compressed pulse can have pulse energy in a range of about 1 nJ and about 10 mJ. The ultrafast laser system can further include a polarization rotation device positioned between the amplifier and the second chirped reflective Bragg grating, wherein the polarization rotation device is configured to rotate polarizations of the amplified laser pulse and the compressed laser pulse to produce a polarization-rotated laser pulse having a polarization perpendicular to the polarization of the amplified laser pulse; and a polarizer that can allow the polarization-rotated laser pulse to be output by the output coupler.

Implementations of the system may include one or more of the following. The seed laser system can further include a semiconductor saturation absorber package (SESAM) that can lock a resonance mode in at least one of the signal laser pulse or the stretched signal laser pulse. The chirped reflective Bragg grating and the SESAM can in part define a resonance cavity for the signal laser pulse. The stretched pulse width can be in a range of about 10 fs to 100 ps. The stretched signal laser pulse can have pulse energy in a range of about 10 pJ and about 1 nJ.

Embodiments may include one or more of the following advantages. The described ultrafast laser systems are more compact than some conventional laser systems, which allow the described laser systems to be used in a wider range of applications. The described fiber-based laser systems are simpler and less costly than some convention CPA laser systems that use pair of bulk gratings. The described fiber-based laser systems provide better control for stretching and compressing laser pulses than some conventions systems, which makes the described laser systems suitable for ultrafast laser applications. The disclosed fiber-based laser systems are also thermally and environmentally stable, and can resist thermal damages and environmental perturbation. Furthermore, the disclosed ultrafast laser system is applicable to seed lasers and high energy laser systems with active power amplification.

### BRIEF DESCRIPTION OF THE DRAWINGS

The following drawings, which are incorporated in and from a part of the specification, illustrate embodiments of the present specification and, together with the description, serve to explain the principles of the specification.

FIG. 1 is a schematic diagram of an exemplified fiber-based ultrafast laser system having a stretcher and a compressor based on reflective Bragg gratings.

FIG. 2 is a schematic diagram of another exemplified fiber-based ultrafast laser system having a stretcher and a compressor based on reflective Bragg gratings.

FIG. 3 is a graph showing the dependence of dispersion on grating chirp and grating length of a reflective Bragg grating.

FIG. 4 is a schematic diagram of an exemplified seed laser (oscillator) including a reflective Bragg grating for dispersion control.

### DETAILED DESCRIPTION

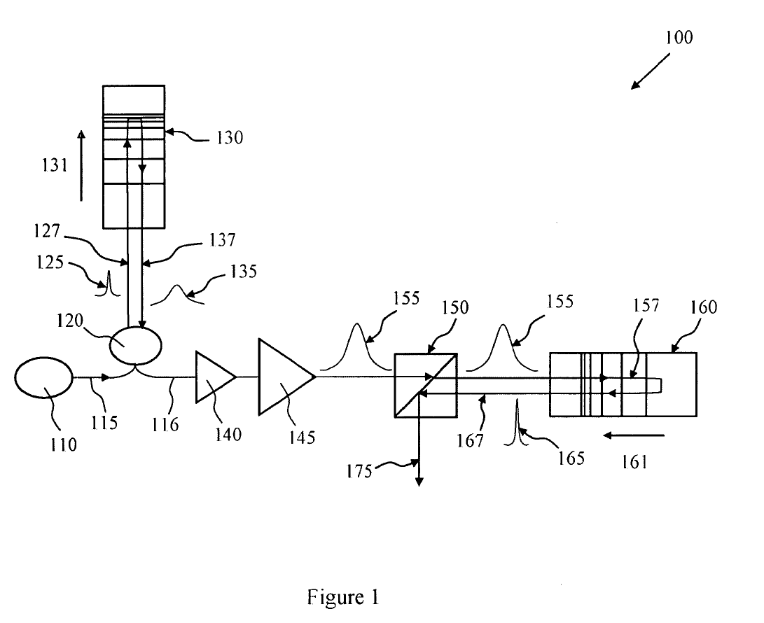

Referring to FIG. 1, a fiber-based ultrafast laser system 100 includes a seed laser 110 configured to produce ultrafast signal laser pulses and a coupler 120 configured to receive the ultrafast signal laser pulses from the seed laser 110 via an optical fiber 115. The ultrafast signal laser pulse can have pulse energy from 10 pJ to 1 nJ and a pulse width from 10 fs to 100 ps. The seed laser 110 can include a femtosecond fiber laser oscillator. The coupler 120 can implemented as a 3 dB optical coupler or a circulator. The coupler 120 can direct an ultrafast signal laser pulse 125 toward a chirped reflective Bragg grating 130.

The chirped reflective Bragg grating 130 includes an optical fiber having reflective grating along a longitudinal direction 131 of the optical fiber. The optical fiber can have a length ranging from 0.5 cm to 5 cm. The grating frequency (also called as “groove density”) is chirped along the longitudinal direction 131. The reflective grating can be implemented, for example, by refractive index modulations along the longitudinal direction 131. The grating frequency can increase or decrease along the longitudinal direction 131. The ultrafast signal laser pulse 125 along the optical path 127 enters the chirped reflective Bragg grating 130 along the longitudinal direction 131, and is reflected by the chirped Bragg grating 130. The nonlinear optical dispersion in the chirped reflective Bragg grating 130 expands the pulse width of the ultrafast signal laser pulse 125.

Optical dispersion refers to the phenomenon that the group velocity of a light pulse travelling in a medium varies as a function of the light wave's frequency. A short light pulse tends to spread as it travels in the medium as a result of the different velocities of the short light pulse at different frequencies. Optical dispersion can be often quantified by group delay dispersion parameter:

$$D = - \frac{λ}{c} \frac{{d}^{2} n}{d {λ}^{2}} . \qquad ( 1 )$$

A medium is said to have anomalous dispersion if D is larger than zero. A medium has normal dispersion if D is less than zero. If a light pulse propagates through a normal dispersive medium, the higher frequency components travel faster than the lower frequency components. The pulse therefore becomes positively chirped, or up-chirped, increasing in frequency with time. Conversely, if a pulse travels through an anomalous dispersion medium, lower frequency components travel faster than the lower ones, and the pulse becomes negatively chirped, or down-chirped, decreasing in frequency with time.

A reflected laser pulse 135 travels along optical path 137 has a longer pulse width than the ultrafast signal laser pulse 125. For example, the laser pulse 135 can have a pulse width stretched from 10 ps to 5 ns. The laser pulse 135 can have a stretched pulse width several times to tens of thousands times longer than the ultrafast signal laser pulse 125. The chirped reflective Bragg grating 130 thus functions a pulse stretcher. The extent of pulse stretching is dependent on, among other parameters, the chirp rate of the grating, the bandwidth of the grating, and the bandwidth of the laser pulses. The bandwidth of the grating is typically broader than the bandwidth of the laser pulses.

An exemplified material for the chirped reflective Bragg grating 130 (and 160 described below) was a type of glass called photo-thermal refractive (PTR) glass. PTR glass can be made by a multi-component sodium-zinc-aluminum-silicate doped with cerium, silver, and fluorine, which can be made in the form of optical fibers or single-piece bulk components with a length ranging from a few millimeters to a few centimeters. Refractive index modulation in PTR can be realized by UV exposure over portions of the PTR material and thermal annealing. Its refractive index decreases after UV exposure followed by a high temperature thermal annealing process. The recorded grating pattern in the PTR glass is stable under optical illumination and can withstand high temperature elevation up to 400° C. The achievable modulation of refractive index is in the range of 10⁻³. Consequently, broad chirp bandwidths of few 10's of nanometers should be possible, similar to what has been demonstrated in chirped fiber Bragg gratings. PTR glass has low absorption within 350 nm to 2700 nm spectral window, which enables PTR glass based gratings to withstand high average powers in this spectral window. The measured PTR glass surface damage threshold of 20 J/cm² (measured at 1054 nm for I-ns pulse duration) is similar to that of fused silica. The high damage threshold and low absorption make PTR glass attractive for high energy and high power applications. The grating pattern inside the PTR glass was recorded by holographic method using a CW radiation of a He—Cd laser at 325 nm. The UV writing beam was split into two arms and then redirected to cross each other with one arm collimated and the other arm diverging after a cylindrical lens. A tilted chirped interference pattern was created. The PTR glass sample was then placed at the beam crossover position with same slant angle as the interference pattern so that chirped pattern was parallel to the input and output surfaces. A post-recording annealing process was used to reveal the grating.

The laser pulse 135 is guided by an optical fiber 116 to one or more fiber amplifiers 140 and 145, which amplify the stretched laser pulse 135 and output a high energy (or amplified) laser pulse 155. The high energy laser pulse 155 passes through an output coupler 150 to enter a chirped reflective Bragg grating 160. The high energy pulse can have a pulse energy ranged from 5 nJ to 5 mJ and a pulse width from 10 ps to 5 ns. The high energy pulse 155 is preferably polarized. The output coupler 150 can be fiber based or a polarization beam splitter. The chirped reflective Bragg grating 160 can be fiber based. The chirped reflective Bragg grating 160 is preferably a single-piece bulk component, which is more resistive to surface damage, material breakdown, and thermal damages generated by high energy laser pulses. The chirped reflective Bragg grating 160 has chirped grating frequency along a longitudinal direction 161. The reflective grating can be implemented, for example, by refractive index modulations along the longitudinal direction 161.

The grating frequency (or the grating fringe modulation frequency) increases or decreases along the longitudinal direction 161 in the same trend as the grating frequency changes along the longitudinal direction 131 in the chirped reflective Bragg grating 130. For example, grating frequencies can increase along the longitudinal directions 131 and 161 in their respective chirped reflective Bragg gratings 130 and 160. Alternatively, the grating frequencies can also decrease along the longitudinal directions 131 and 161 in their respective chirped reflective Bragg gratings 130 and 160. The propagation path 157 of the high energy stretched laser pulse 155 experiences a grating frequency change substantially opposite to the grating frequency change in the longitudinal direction 161. The high energy pulse 155 thus experience an opposite optical dispersion in the chirped reflective Bragg grating 160 from the optical dispersion that the signal laser pulse 125 experienced in the chirped reflective Bragg grating 130. Inter other words, the signs of optical dispersions produced by the chirped reflective Bragg gratings 130 and 160 are opposite relative to their respective laser pulses 125 and 155. If the optical dispersion produced by the chirped reflective Bragg grating 130 is positive, then the optical dispersion produced by the chirped reflective Bragg grating 160 is negative, and vice versa. The high energy stretched laser pulse 155 is thus compressed by the chirped reflective Bragg grating 160. The high energy stretched laser pulse 155 is reflected by chirped refractive index modulations to form an ultrafast laser pulse 165 that has a compressed pulse width compared to the high energy stretched laser pulse 155.

The chirped reflective Bragg grating 160 thus functions a pulse compressor. The ultrafast laser pulse 165 is directed to the output coupler 150 along optical path 167 and then travels along optical path 175 as an output. The ultrafast laser pulse 165 can be in transform limited shape such as soliton, Gaussian, or parabolic shapes; and can also be non-transform limited. The ultrafast laser pulse 165 can have pulse energy from 1 nJ to 10 mJ, or from 3 nJ to 4 mJ and a pulse width ranging from 10 fs to 100 ps. In some embodiments, the pulse width for the ultrafast laser pulse 165 is similar to the pulse width of the signal laser pulse 125.

As described below, the extent of pulse compression is dependent on, among other parameters, the chirp rate of the chirped reflective Bragg grating, the bandwidth of the grating, and the bandwidth of the laser pulses. The bandwidth of the grating should be larger than the bandwidth of the laser pulses. In some embodiments, the chirped reflective Bragg grating 160 and 130 can be designed to minimize third order dispersion (TOD) (to close to zero), the ultrafast laser pulse 165 can be compressed to have substantially the same pulse width as the original ultrafast signal laser pulse from the seed laser 110.

In some aspects, the chirped reflective Bragg grating 130 provides a chirping function to the input laser ultrafast pulse, while the chirped reflective Bragg grating 160 provides de-chirping function to the stretched and amplified laser pulse. In some embodiments, the chirped reflective Bragg grating 130 and the chirped reflective Bragg grating 160 can be both fiber based or a single-piece bulk component to further reduce component sizes in the fiber-based ultrafast laser system 100.

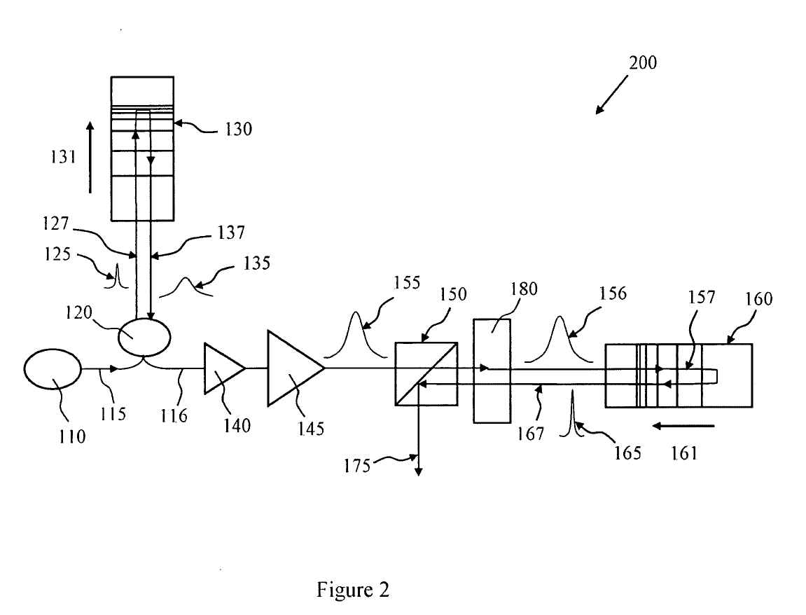

In some embodiments, the chirped reflective Bragg gratings 130, 160 can be implemented by a single chirped reflective Bragg grating shared by pulse stretching and pulse compression. The ultrafast signal laser pulse 125 enters the shared chirped reflective Bragg grating in a longitudinal direction. The grating frequency varies (increase or decrease) along the longitudinal direction to enable pulse stretching. The high energy stretched laser pulse 155 (or the high energy stretched laser pulse 156 in FIG. 2 as described below) can enter the shared chirped reflective Bragg grating component along a direction opposite to the direction of the signal pulse 125. The grating frequency thus varies oppositely along the propagations of the high energy stretched laser pulse 155 and the ultrafast signal laser pulse 125. The high energy stretched laser pulse 155 is thus compressed by the shared chirped reflective Bragg grating.

In some embodiments, referring to FIG. 2, an ultrafast laser system 100 can include a polarization rotation device 180 positioned between the output coupler 150 and the chirped reflective Bragg gratings 160. The polarization rotation device 180 is in the optical path for the high energy stretched laser pulse 155 and the ultrafast laser pulse 165. The polarization rotation device 180 can include a Faraday rotator or phase retardation material such as a quarter wave plate. The polarization rotation device 180 can rotate the polarization of the high energy laser pulse 155 to produce a high energy laser pulse 156 that enters the chirped reflective Bragg gratings 160. The polarization rotation device 180 can rotate the polarization of the ultrafast laser pulse 165 such that at the output coupler 150, the ultrafast laser pulse 165 has a polarization perpendicular to the polarization of the high energy laser pulse 155. The output coupler 150 can be a polarization beam splitter (PBS) that allows the ultrafast laser pulse 165 has a polarization having the rotated perpendicular polarization to be output along the optical path 175. The polarization rotation device 180 and the PBS can thus prevent stray or other unwanted high energy laser beams from entering the amplifiers 140, 145, which can thus prevent damage to the amplifiers 140, 145 by these high energy laser beams. An isolator may need to be put between 145 and 150 to further prevent reflected light from entering into amplifier 140 and 145. One or more of the optical fibers 115 and 116 and other optical fibers in the fiber-based ultrafast laser system 100 can maintain the polarization.

The extent of pulse stretching and pulse compression of the chirped reflective Bragg gratings 130, 160 can be designed by properly selecting structural parameters of the chirped reflective Bragg gratings 130, 160. The dispersion of a laser beam by a chirped grating can be expressed as

$$D = \frac{2 {L}_{g}}{Δ {λ}_{chirp} {v}_{g}} \qquad ( 2 )$$

where Lg is the grating length, v_{g} is the group velocity, and Δλ_{chirp} is the chirp bandwidth

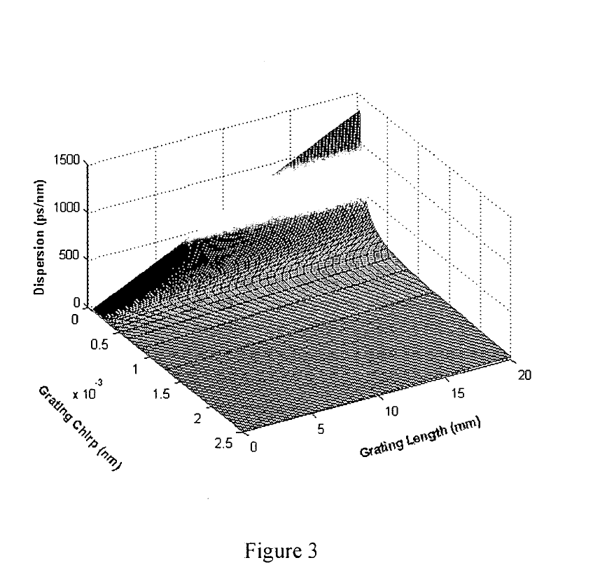

Δλ_{chirp}=2n_{eff}(Λ_{long}−Λₛₕₒᵣₜ)=2n_{eff}ΔΛ_{chirp}. (3)

Where in ΔΛ_{chirp} is the grating chirp, Λ_{long} is the grating period for long wavelength and Λₛₕₒᵣₜ is the grating period for short wavelength. n_{eff} is the effective refractive index of the grating. FIG. 3 shows simulation results for dispersion as a function of rating chirp and grating length. Dispersion increases with a decrease in chirp rate and an increase in the grating length.

The pulse width of a laser pulse propagating in a chirped reflective Bragg grating is affected by the dispersion produced by the chirped reflective Bragg grating. For example, pulse broadening or compressing for a Gaussian pulse can be written as

$${( \frac{{T}_{1}}{{T}_{0}} )}^{2} = 1 + 2 π c \frac{Δ {λ}_{chirp}^{2} {DL}_{s}}{{λ}^{2}} \qquad ( 4 )$$

wherein T1 is the output pulse width; T0 is the input pulse width, D is the fiber grating dispersion, and c is the velocity of light. The degree of pulse stretching or compression increases with the absolute value of the dispersion D, while the signs for D are opposite for pulse stretching and pulse compression.

If we introduce a figure of merit (FOM) for the bandwidth of the grating, we can redefine Equation (3) by recognizing that the dispersion of the grating is almost 10 ns/m/δλ_{chirp}. So, the pulse broadening or compressing value can be written in the form of

$$Δ {T}^{2} = {M}^{2} = \frac{2 π c}{{λ}^{2}} ( Δ {λ}_{chirp}^{2} {L}_{g} \times {10}^{- 8} ) \qquad ( 5 )$$

It can be seen that laser pulse width can be varied by changing the chirp rate and selecting an appropriate length of the grating. The above described design approach is applicable to fiber-based or single-piece bulk chirped reflective Bragg gratings. The pulse widths include but not limited to femtosecond and picosecond ultrafast laser pulses.

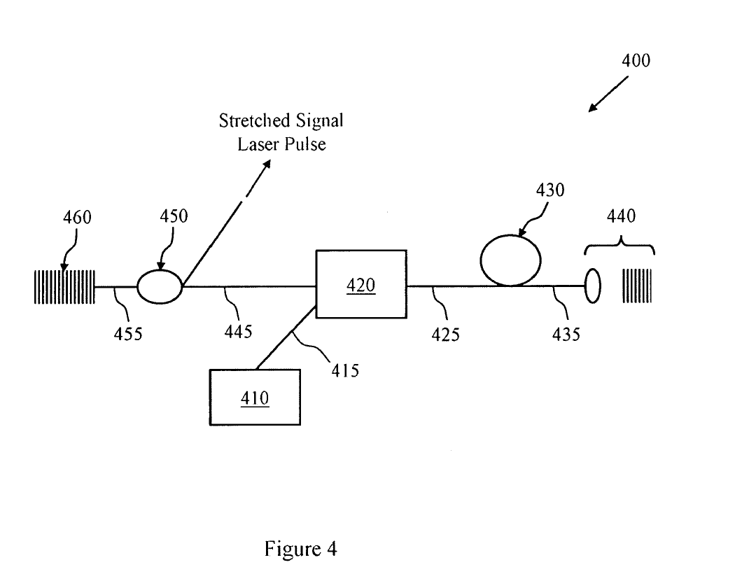

In some embodiments, fiber-based chirped reflective Bragg gratings can be incorporated in a seed laser to produce high degree of device integration, and further reduce device size and cost. Referring to FIG. 4, an integrated seed laser 400 includes a laser pump source 410 configured to generate a source laser beam and a combiner 420 configured to receive the source laser beam via an optical fiber 415 and couple it into an optical fiber 425. The source laser beam from the laser pump source 410 can for example be at 980 nm. The combiner 420 can be a Wavelength Division Multiplexing (WDM) coupler. The integrated seed laser 400 also includes a gain fiber 430, a semiconductor saturation absorber package (SESAM) 440, an output coupler 450, and a chirped reflective Bragg grating 460. An optical fiber 415 can guide a pump laser beam from the laser pump source 410 to the combiner 420. Optical fibers 425, 435, 445, 455 can guide the signal laser beam among the combiner 420, the gain fiber 430, the SESAM 440, the output coupler 450, and the chirped reflective Bragg grating 460. The gain fiber 430 can produce a signal laser pulse in response to the power provided by the source laser beam. The chirped reflective Bragg grating 460 can stretch the signal laser pulse to produce a stretched signal laser pulse. The output coupler 450 can output at least a portion of the stretched signal laser pulse.

The laser cavity for the signal laser beam is defined between two reflective components: the SESAM 440 and the chirped reflective Bragg grating 460, which act as mirrors for resonance cavities for the signal laser and the stretched beam. The SESAM 440 can trigger mode locking for the signal laser beam containing the signal laser pulse and the stretched laser beam comprising the stretched signal laser pulse. The signal laser beam is reflected between the two reflective components and amplified by the gain fiber 430. In addition to reflection, the chirped reflective Bragg grating 460 can also stretch the signal laser pulse based on its anomalous optical dispersion as described above. The chirped reflective Bragg grating 460 can provide mode locking to the signal laser beam. Exemplified wavelength ranges for the signal laser beam is from about 1030 nm to about 1100 nm for Yb-doped fiber laser, or from 1520-1610 nm for Er-doped fiber laser. The output stretched signal laser pulse can have pulse energy in a range from 10 pJ to 1 nJ and pulse width from 10 fs to 100 ps.

An advantage of the described seed laser system is that it can be more compact than conventional systems because it can be all based on fiber components. The described seed laser can enable miniaturized high energy laser designs. For example, the integrated seed laser 400 can replace the seed laser 110, the coupler 120, and the chirped reflective Bragg grating 130 in the fiber-based ultrafast laser system 100. The stretched laser pulses can be directly fed into amplifiers to generate high energy pulses and subsequently compressed to form ultrafast pulses.

It is understood the disclosed systems and methods are compatible with other variations. The disclosed ultrafast laser systems can include different configurations and include different or additional components without deviating from the spirit of the invention. The disclosed ultrafast laser systems are applicable to seed lasers and high energy laser systems with active power amplification. The wavelengths of the signal laser beam and the amplified laser beams can be different from the examples described above. Pulse widths, the extent of pulse stretching and compression can also be different from the examples described above.

What is claimed is:

1. An ultrafast laser system, comprising:
a seed laser configured to provide a signal laser pulse;
a first chirped reflective Bragg grating constructed in an optical fiber, wherein the first chirped reflective Bragg grating is configured to reflect the signal laser pulse and to produce a stretched laser pulse longer than the signal laser pulse, wherein the signal laser pulse propagates along a first path in the first chirped reflective Bragg grating, wherein a grating frequency of the first chirped reflective Bragg grating varies along the first path;
an amplifier configured to amplify the stretched laser pulse and to output an amplified laser pulse;
a second chirped reflective Bragg grating configured to reflect the amplified laser pulse and to produce a compressed laser pulse shorter than the amplified laser pulse, wherein the amplified laser pulse propagates along a second path in the second chirped reflective Bragg grating, wherein a grating frequency of the second chirped reflective Bragg grating varies in an opposite direction along the second path as the grating frequency of the first chirped reflective Bragg grating varies along the first path; and
an output coupler configured to output at least a portion of the compressed laser pulse, wherein the compressed laser pulse has a compressed pulse width shorter than 1 nanosecond.

2. The ultrafast laser system of claim 1, wherein the grating frequency of the first chirped reflective Bragg grating increases along the first path, and wherein the grating frequency of the second chirped reflective Bragg grating decreases along the second path.

3. The ultrafast laser system of claim 1, wherein the grating frequency of the first chirped reflective Bragg grating decreases along the first path, and wherein the grating frequency of the second chirped reflective Bragg grating increases along the second path.

4. The ultrafast laser system of claim 1, wherein the first chirped reflective Bragg grating produces a positive optical dispersion in the signal laser pulse, and wherein the second chirped reflective Bragg grating produces a negative optical dispersion in the amplified laser pulse.

5. The ultrafast laser system of claim 1, wherein the first chirped reflective Bragg grating produces a negative optical dispersion in the signal laser pulse, and wherein the second chirped reflective Bragg grating produces a positive optical dispersion in the amplified laser pulse.

6. The ultrafast laser system of claim 1, further comprising one or more optical fibers configured to allow propagation of the signal laser pulse, the stretched laser pulse, the amplified laser pulse, and the compressed laser pulse between the seed laser and the second chirped reflective Bragg grating.

7. The fiber-based ultrafast laser of claim 6, wherein the one or more optical fibers comprises at least one polarization maintaining fiber.

8. The ultrafast laser system of claim 1, wherein the second chirped reflective Bragg grating is constructed by a single-piece bulk component.

9. The ultrafast laser system of claim 1, wherein the second chirped reflective Bragg grating is constructed in an optical fiber.

10. The ultrafast laser system of claim 1, wherein the first chirped reflective Bragg grating and the second chirped reflective Bragg grating are implemented by a shared chirped reflective Bragg grating, wherein the first path is opposite to the second path in the shared chirped reflective Bragg grating.

11. The ultrafast laser system of claim 1, wherein the compressed pulse width is shorter than 100 picoseconds.

12. The ultrafast laser system of claim 11, wherein the compressed pulse width is shorter than 1 picosecond.

13. The ultrafast laser system of claim 1, wherein the compressed pulse has a pulse energy in a range of about 1 nJ and about 10 mJ.

14. The ultrafast laser system of claim 1, further comprising:
a polarization rotation device positioned between the amplifier and the second chirped reflective Bragg grating, wherein the polarization rotation device is configured to rotate polarizations of the amplified laser pulse and the compressed laser pulse to produce a polarization-rotated laser pulse having a polarization perpendicular to the polarization of the amplified laser pulse; and
a polarizer configured to allow the polarization-rotated laser pulse to be output by the output coupler.

15. An ultrafast laser system, comprising:
a seed laser configured to provide a signal laser pulse;
a chirped reflective Bragg grating configured to reflect the signal laser pulse and to produce a stretched laser pulse longer than the signal laser pulse, wherein the signal laser pulse propagates along a first direction in the chirped reflective Bragg grating, wherein a grating frequency of the chirped reflective Bragg grating varies along the first direction;
an amplifier configured to amplify the stretched laser pulse and to output an amplified laser pulse, wherein the amplified laser pulse is configured to propagate along a second direction in the chirped reflective Bragg grating, wherein the second direction is opposite to the first direction, wherein the chirped reflective Bragg grating is configured to reflect the amplified laser pulse and to produce a compressed laser pulse shorter than the amplified laser pulse; and
an output coupler configured to output at least a portion of the compressed laser pulse, wherein the compressed laser pulse has a compressed pulse width shorter than 1 nanosecond.

16. The ultrafast laser system of claim 15, wherein the grating frequency of the first chirped reflective Bragg grating increases along the first direction and decreases along the second direction.

17. The ultrafast laser system of claim 15, wherein the grating frequency of the first chirped reflective Bragg grating decreases along the first direction and increases along the second direction.

18. The ultrafast laser system of claim 15, wherein the chirped reflective Bragg grating is configured to produce a positive optical dispersion in the signal laser pulse and a negative optical dispersion in the amplified laser pulse.

19. The ultrafast laser system of claim 15, wherein the chirped reflective Bragg grating is configured to produce a negative optical dispersion in the signal laser pulse and a positive optical dispersion in the amplified laser pulse.

20. The ultrafast laser system of claim 15, further comprising one or more optical fibers configured to allow propagation of the signal laser pulse, the stretched laser pulse, the amplified laser pulse, and the compressed laser pulse between the seed laser and the chirped reflective Bragg grating.

21. The ultrafast laser system of claim 15, wherein the chirped reflective Bragg grating is constructed in an optical fiber or in a single-piece bulk component.

22. The ultrafast laser system of claim 15, wherein the compressed pulse width is shorter than 100 picoseconds.

23. The ultrafast laser system of claim 15, wherein the compressed pulse has a pulse energy in a range of about 1 nJ and about 10 mJ.

24. The ultrafast laser system of claim 15, further comprising:
a polarization rotation device positioned between the amplifier and the chirped reflective Bragg grating, wherein the polarization rotation device is configured to rotate polarizations of the amplified laser pulse and compressed laser pulse to produce a polarization-rotated laser pulse having a polarization perpendicular to the polarization of the amplified laser pulse; and
a polarizer configured to allow the polarization-rotated laser pulse to be output by the output coupler.

25. A seed laser system, comprising:
a laser pump source configured to provide a pump laser beam;
a gain fiber configured to produce a signal laser pulse in response to the pump laser beam;
a combiner configured to couple the pump laser beam into the gain fiber;
a chirped reflective Bragg grating configured to reflect the signal laser pulse and to produce a stretched signal laser pulse longer than the signal laser pulse, wherein the stretched signal laser pulse is longer than the signal laser pulse;
one or more optical fibers configured to allow propagation of the signal laser pulse between the gain fiber and the chirped reflective Bragg grating; and
an output coupler configured to output at least a portion of the stretched signal laser pulse.

26. The seed laser system of claim 25, further comprising a semiconductor saturation absorber package (SESAM) configured to mode lock at least one of the signal laser pulse or the stretched signal laser pulse.

27. The seed laser system of claim 26, wherein the chirped reflective Bragg grating and the SESAM in part define a resonance cavity for the signal laser pulse.

29. The seed laser system of claim 25, wherein the stretched pulse width is in a range of about 10 fs to 100 ps.

30. The seed laser system of claim 25, wherein the stretched signal laser pulse has pulse energy in a range of about 10 pJ and about 1 nJ.
